(19) United States
(12) Patent Application Publication
(10) Pub. No.: US 2023/0307228 A1
(43) Pub. Date: Sep. 28, 2023

(54) PIXELATED SHOWERHEAD FOR RF SENSITIVE PROCESSES

(71) Applicant: Applied Materials, Inc., Santa Clara, CA (US)

(72) Inventors: Abdul Aziz Khaja, San Jose, CA (US); Juan Carlos Rocha-Alvarez, San Carlos, CA (US)

(73) Assignee: Applied Materials, Inc., Santa Clara, CA (US)

(21) Appl. No.: 17/703,537

(22) Filed: Mar. 24, 2022

(51) Int. Cl. H01L 21/02; H01J 37/32

(52) U.S. Cl. CPC H01L 21/02274; H01J 37/3244; H01J 37/32715; H01J 2237/332

(57) ABSTRACT

Exemplary semiconductor processing chambers may include a gas delivery assembly. The chambers may include a substrate support. The chambers may include a faceplate positioned between the gas delivery assembly and the substrate support. The faceplate may be characterized by a first surface and a second surface. The second surface of the faceplate and the substrate support may at least partially define a processing region. The faceplate may define a first plurality of apertures and a second plurality of apertures. Each of the first plurality of apertures may include a first generally conical aperture profile that extends through the second surface that extends through the second surface. Each of the second plurality of apertures may include a second generally conical aperture profile that extends through the second surface. The second generally conical aperture profile may be different than the first generally conical aperture profile.

### TECHNICAL FIELD

The present technology relates to components and apparatuses for semiconductor manufacturing. More specifically, the present technology relates to processing chamber distribution components and other semiconductor processing equipment.

### BACKGROUND OF THE INVENTION

Integrated circuits are made possible by processes which produce intricately patterned material layers on substrate surfaces. Producing patterned material on a substrate requires controlled methods for forming and removing material. Chamber components often deliver processing gases to a substrate for depositing films or removing materials. To promote symmetry and uniformity, many chamber components may include regular patterns of features, such as apertures, for providing materials in a way that may increase uniformity. However, this may limit the ability to tune recipes for on-wafer adjustments.

Thus, there is a need for improved systems and methods that can be used to produce high quality devices and structures. These and other needs are addressed by the present technology.

### BRIEF SUMMARY OF THE INVENTION

Exemplary semiconductor processing chambers may include a gas delivery assembly. The chambers may include a substrate support. The chambers may include a faceplate positioned between the gas delivery assembly and the substrate support. The faceplate may be characterized by a first surface facing the gas delivery assembly and a second surface opposite the first surface. The second surface of the faceplate and the substrate support may at least partially define a processing region within the semiconductor processing chamber. The faceplate may define a first plurality of apertures and a second plurality of apertures through the faceplate. Each of the first plurality of apertures may include a first generally conical aperture profile that extends through the second surface of the faceplate that extends through the second surface of the faceplate. Each of the second plurality of apertures may include a second generally conical aperture profile that extends through the second surface of the faceplate. The second generally conical aperture profile may be different than the first generally conical aperture profile.

In some embodiments, the second generally conical aperture profile and the first generally conical aperture profile may include a different height, a different angle, or both a different height and a different angle. The first generally conical aperture profile may extend though the first surface of the faceplate. Each of the first plurality of apertures may include an upper aperture profile that extends through the first surface of the faceplate. The upper aperture profile may be characterized by a substantially cylindrical profile. Each of the first plurality of apertures may be disposed within one of a plurality of clusters of one or more apertures. The plurality of clusters may be distributed irregularly about the faceplate. A portion of each of the first plurality of apertures and a portion of each of the second plurality of apertures may be characterized by a same diameter. The first plurality of apertures may be arranged about the faceplate in one or more zones. Each of the one or more zones may include multiple apertures of the first plurality of apertures. Each of the one or more zones may be arranged about the second surface in a shape selected from the group consisting of a radial shape, an annular shape, an arcuate shape, a circle, and a polygon.

Some embodiments of the present technology may encompass semiconductor processing chamber faceplates. The faceplates may include a first surface and a second surface opposite the first surface. The faceplate may define a first plurality of apertures and a second plurality of apertures through the faceplate. Each of the first plurality of apertures may include a first generally conical aperture profile that extends through the second surface of the faceplate that extends through the second surface of the faceplate. Each of the second plurality of apertures may include a second generally conical aperture profile that extends through the second surface of the faceplate. The second generally conical aperture profile may be different than the first generally conical aperture profile. An angle of each first generally conical aperture profile and each second generally conical aperture profile may be between about 5 degrees and 85 degrees relative to the second surface of the faceplate. A length of each first generally conical aperture profile and each second generally conical aperture profile may be between about 0.1 inches and 0.5 inches. The faceplate may define a third plurality of apertures through the faceplate. Each of the third plurality of apertures may include a third generally conical aperture profile that extends through the second surface of the faceplate. The third generally conical aperture profile may be different than the first generally conical aperture profile and the second generally conical aperture profile. The faceplate may define a third plurality of apertures through the faceplate. Each of the third plurality of apertures may include a generally cylindrical aperture profile that extends through the second surface of the faceplate. The first plurality of apertures may be disposed within a central region of the faceplate. The second plurality of apertures may be disposed within an outer region that is radially outward of the central region. The central region may be generally circular or polygonal in shape. The outer region may be generally annular in shape. A length of each first generally conical aperture profile and each second generally conical aperture profile may extend through between about 5% and 50% of a thickness of the faceplate. The faceplate may include a central region, an outer region, and an intermediate region disposed between the central region and the outer region. At least some of the first plurality of apertures may be disposed within the central region of the faceplate. At least some of the first plurality of apertures may be disposed within the outer region of the faceplate. At least some of the second plurality of apertures may be disposed within the intermediate region.

Some embodiments of the present technology may encompass semiconductor processing chamber faceplates. The faceplates may include a first surface and a second surface opposite the first surface. The faceplate may define a plurality of apertures through the faceplate. Each of the plurality of apertures may include a generally conical aperture profile. At least some of the generally conical aperture profiles may have a different height, a different angle, or both a different height and a different angle.

In some embodiments, the faceplate may include apertures having at least five different types of generally conical aperture profiles. A single type of the generally conical aperture profiles may be present in no more than 50% of the plurality of apertures of the faceplate.

Such technology may provide numerous benefits over conventional systems and techniques. For example, embodiments of the present technology may allow controlled tuning of the hollow cathode effect and ion flux, which may enable localized deposition rates to be carefully controlled to improve film uniformity on wafer. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary plasma system according to some embodiments of the present technology.

FIG. 3 shows a schematic partial cross-sectional view of an exemplary faceplate according to some embodiments of the present technology.

FIG. 4A shows a schematic bottom plan view of an exemplary faceplate according to some embodiments of the present technology.

FIG. 4B shows a schematic bottom plan view of an exemplary faceplate according to some embodiments of the present technology.

FIG. 4C shows a schematic bottom plan view of an exemplary faceplate according to some embodiments of the present technology.

FIG. 4D shows a schematic bottom plan view of an exemplary faceplate according to some embodiments of the present technology.

FIG. 4E shows a schematic bottom plan view of an exemplary faceplate according to some embodiments of the present technology.

FIG. 4F shows a schematic bottom plan view of an exemplary faceplate according to some embodiments of the present technology.

FIG. 5 shows operations of an exemplary method of semiconductor processing according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION OF THE INVENTION

Plasma enhanced deposition processes may energize one or more constituent precursors to facilitate film formation on a substrate. Any number of material films may be produced to develop semiconductor structures, including conductive and dielectric films, as well as films to facilitate transfer and removal of materials. For example, hardmask films may be formed to facilitate patterning of a substrate, while protecting the underlying materials to be otherwise maintained. In many processing chambers, a number of precursors may be mixed in a gas panel and delivered to a processing region of a chamber where a substrate may be disposed. The precursors may be distributed through one or more components within the chamber, which may produce a radial or lateral distribution of delivery to provide increased formation or removal at the substrate surface.

As device features reduce in size, tolerances across a substrate surface may be reduced, and material property differences across a film may affect device realization and uniformity. Many chambers include a characteristic process signature, which may produce non-uniformity across a substrate. Temperature differences, flow pattern uniformity, and other aspects of processing may impact the films on the substrate, creating film uniformity differences across the substrate for materials produced or removed. For example, one or more devices may be included within a processing chamber for delivering and distributing precursors within a processing chamber. A blocker plate may be included in a chamber to provide a choke in precursor flow, which may increase residence time at the blocker plate and lateral or radial distribution of precursors. A faceplate may further improve uniformity of delivery into a processing region, which may improve deposition or etching. Some systems may also use texture and/or emissivity patterns on chamber components to adjust a deposition rate on wafer. However, such features only work for temperature sensitive processes, and have no effect on RF sensitive processes.

The present technology overcomes film non-uniformity challenges during RF sensitive processes by utilizing faceplates that include apertures that are characterized by different aperture profiles. In particular, at least some of the aperture profiles include conical sections that alter the hollow cathode effects and ion flux exhibited at each aperture, which subsequently alters the localized deposition rate proximate the aperture. The height and/or taper of the conical sections may be adjusted to effectively tune the localized deposition rate, which may enable film thickness uniformity to be improved in RF sensitive processes. The number of zones and different aperture profiles utilized may be selected to achieve a desired film thickness profile and/or uniformity threshold. Accordingly, the present technology may produce improved film deposition characterized by improved uniformity across a surface of the substrate.

Although the remaining disclosure will routinely identify specific deposition processes utilizing the disclosed technology, it will be readily understood that the systems and methods are equally applicable to other deposition and cleaning chambers, as well as processes as may occur in the described chambers. Accordingly, the technology should not be considered to be so limited as for use with these specific deposition processes or chambers alone. The disclosure will discuss one possible system and chamber that may include lid stack components according to embodiments of the present technology before additional variations and adjustments to this system according to embodiments of the present technology are described.

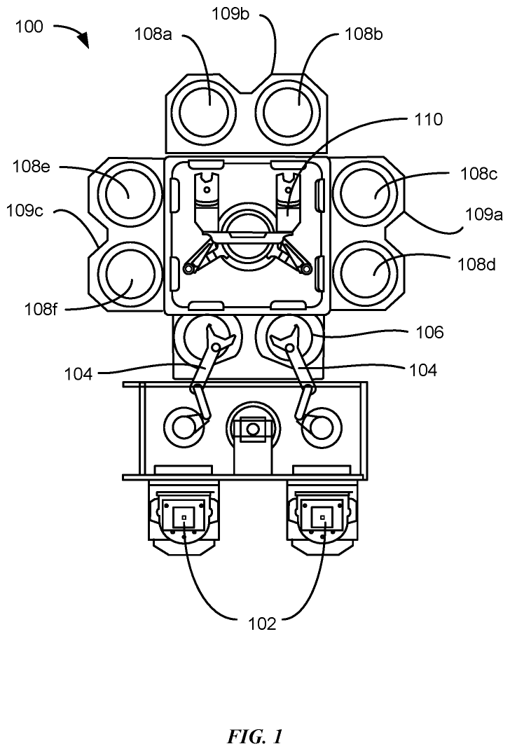

FIG. 1 shows a top plan view of one embodiment of a processing system 100 of deposition, etching, baking, and curing chambers according to embodiments of the present technology. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

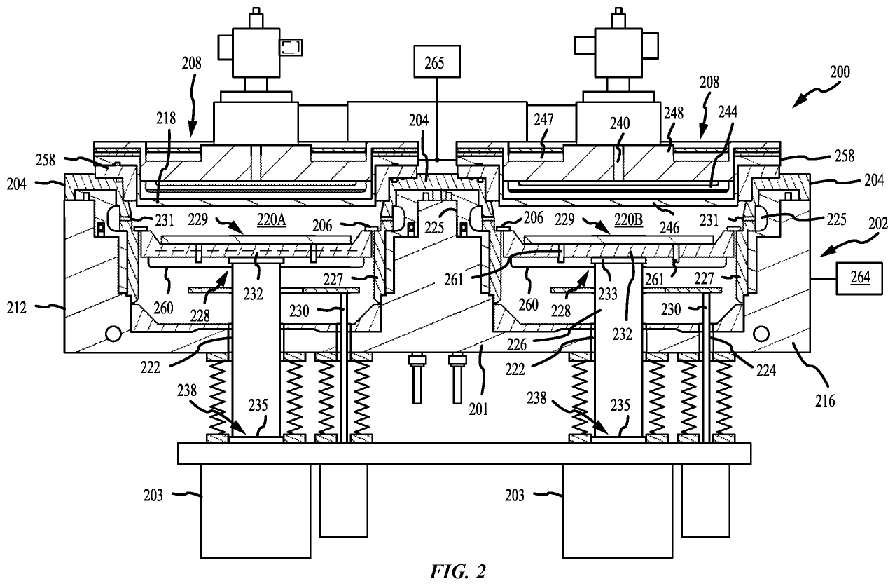

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include faceplates or other components or assemblies according to embodiments of the present technology as further described below. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a gas delivery assembly 218 into the processing region 220B. The gas delivery assembly 218 may include a gasbox 248 having a blocker plate 244 disposed intermediate to a faceplate 246. A radio frequency (“RF”) source 265 may be coupled with the gas delivery assembly 218, which may power the gas delivery assembly 218 to facilitate generating a plasma region between the faceplate 246 of the gas delivery assembly 218 and the pedestal 228, which may be the processing region of the chamber. In some embodiments, the RF source may be coupled with other portions of the chamber body 202, such as the pedestal 228, to facilitate plasma generation. A dielectric isolator 258 may be disposed between the lid 204 and the gas delivery assembly 218 to prevent conducting RF power to the lid 204. A shadow ring 206 may be disposed on the periphery of the pedestal 228 that engages the pedestal 228.

An optional cooling channel 247 may be formed in the gasbox 248 of the gas distribution system 208 to cool the gasbox 248 during operation. A heat transfer fluid, such as water, ethylene glycol, a gas, or the like, may be circulated through the cooling channel 247 such that the gasbox 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

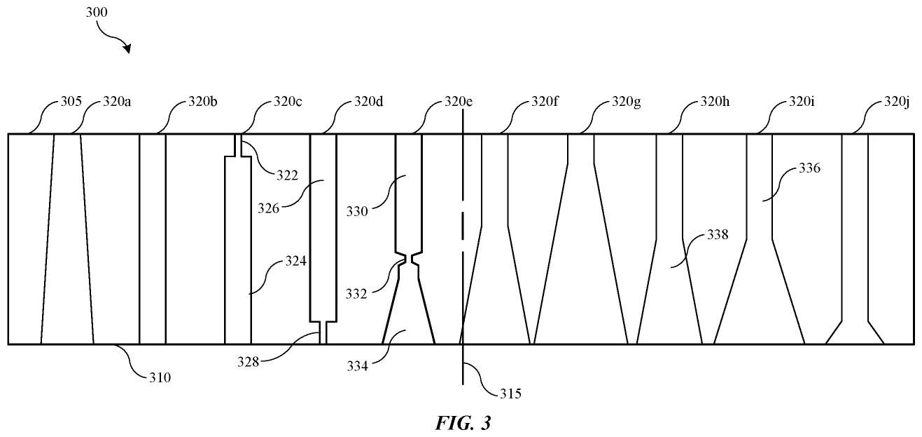

FIG. 3 shows a schematic partial cross-sectional view of an exemplary faceplate 300 according to some embodiments of the present technology. FIG. 3 may illustrate further details relating to components in system 200, such as for faceplate 246. Faceplate 300 is understood to include any feature or aspect of system 200 discussed previously in some embodiments. The faceplate 300 may be used to perform semiconductor processing operations including deposition of hardmask materials as previously described, as well as other deposition, removal, and cleaning operations. Faceplate 300 may show a partial view of a faceplate that may be incorporated in a semiconductor processing system, and may illustrate a view across a center of the faceplate, which may otherwise be of any size, and include any number of apertures. Although shown with a number of apertures extending outward laterally or radially, it is to be understood that the figure is included only for illustration of embodiments, and is not considered to be of scale. For example, exemplary faceplates may be characterized by a number of apertures along a central diameter of greater than or about 20 apertures as will be described further below, and may be characterized by greater than or about 25 apertures, greater than or about 30 apertures, greater than or about 35 apertures, greater than or about 40 apertures, greater than or about 45 apertures, greater than or about 50 apertures, or more.

As noted, faceplate 300 may be included in any number of processing chambers, including system 200 described above. Faceplate 300 may be included as part of the gas inlet assembly, such as with a gasbox and blocker plate. For example, a gasbox may define or provide access into a processing chamber. A substrate support may be included within the chamber, and may be configured to support a substrate for processing. A blocker plate may be included in the chamber between the gasbox and the substrate support. The blocker plate may include or define a number of apertures through the plate. The components may include any of the features described previously for similar components, as well as a variety of other modifications similarly encompassed by the present technology.

Faceplate 300 may be positioned within the chamber between the blocker plate and the substrate support as illustrated previously. Faceplate 300 may be characterized by a first surface 305 and a second surface 310, which may be opposite the first surface. In some embodiments, first surface 305 may be facing towards a blocker plate, gasbox, or gas inlet into the processing chamber. Second surface 310 may be positioned to face a substrate support or substrate within a processing region of a processing chamber. For example, in some embodiments, the second surface 310 of the faceplate and the substrate support may at least partially define a processing region within the chamber. Faceplate 300 may be characterized by a central axis 315, which may extend vertically through a midpoint of the faceplate, and may be coaxial with a central axis through the processing chamber.

Faceplate 300 may define a plurality of apertures 320 defined through the faceplate and extending from the first surface through the second surface. Each aperture 320 may provide a fluid path through the faceplate, and the apertures may provide fluid access to the processing region of the chamber. Depending on the size of the faceplate, and the size of the apertures, faceplate 300 may define any number of apertures through the plate, such as greater than or about 1,000 apertures, greater than or about 2,000 apertures, greater than or about 3,000 apertures, greater than or about 4,000 apertures, greater than or about 5,000 apertures, greater than or about 6,000 apertures, or more. As noted above, the apertures may be included in a set of rings extending outward from the central axis, and may include any number of rings as described previously. The rings may be characterized by any number of shapes including circular or elliptical, as well as any other geometric pattern, such as rectangular, hexagonal, or any other geometric pattern that may include apertures distributed in a radially outward number of rings. The apertures may have a uniform or staggered spacing, and may be spaced apart at less than or about 10 mm from center to center. The apertures may also be spaced apart at less than or about 9 mm, less than or about 8 mm, less than or about 7 mm, less than or about 6 mm, less than or about 5 mm, less than or about 4 mm, less than or about 3 mm, or less.

The rings may be characterized by any geometric shape as noted above, and in some embodiments, apertures may be characterized by a scaling function of apertures per ring. For example, in some embodiments a first aperture may extend through a center of the faceplate, such as along the central axis as illustrated. A first ring of apertures may extend about the central aperture, and may include any number of apertures, such as between about 4 and about 10 apertures, which may be spaced equally about a geometric shape extending through a center of each aperture. Any number of additional rings of apertures may extend radially outward from the first ring, and may include a number of apertures that may be a function of the number of apertures in the first ring. For example, the number of apertures in each successive ring may be characterized by a number of apertures within each corresponding ring according to the equation XR, where X is a base number of apertures, and R is the corresponding ring number. The base number of apertures may be the number of apertures within the first ring, and in some embodiments may be some other number, as will be described further below where the first ring has an augmented number of apertures. For example, for an exemplary faceplate having 5 apertures distributed about the first ring, and where 5 may be the base number of apertures, the second ring may be characterized by 10 apertures, (5)×(2), the third ring may be characterized by 15 apertures, (5)×(3), and the twentieth ring may be characterized by 100 apertures, (5)×(20). This may continue for any number of rings of apertures as noted previously, such as up to, greater than, or about 50 rings. In some embodiments each aperture of the plurality of apertures across the faceplate may be characterized by an aperture profile, which may be the same or different in embodiments of the present technology.

Faceplate 300 may define a number of apertures 320 having any number of aperture profiles. As will be discussed in greater detail below, apertures 320 having a similar aperture profile may be positioned about the faceplate 300 in one or more groups and/or individually at discrete locations to tune a deposition rate within a processing chamber. Each aperture 320 may include an aperture profile that defines a shape of the given aperture 320 from the first surface 305 to the second surface 310 and may control the flow conductance through the aperture 320 and may alter the localized deposition rate due to the hollow cathode effect at each aperture 320. Each aperture profile may include one or more sections. For example, aperture 320a is characterized by an aperture profile having a single generally conical section that may extend from the first surface 305 of the faceplate 300 to the second surface 310. Aperture 320b is characterized by an aperture profile having a single generally cylindrical section that may extend from the first surface 305 of the faceplate 300 to the second surface 310. Aperture 320c is characterized by an aperture profile having a first section 322 that may extend from the first surface 305 of the faceplate 300, and may extend partially through the faceplate 300. In some embodiments, the first section 322 may extend less than or about halfway, or less than or about 25% of the way through a thickness of the faceplate between first surface 305 and second surface 310. First section 322 may be characterized by a substantially cylindrical profile as illustrated. By substantially is meant that the profile may be characterized by a cylindrical profile, but may account for machining tolerances and parts variations, as well as a certain margin of error. A second section 324 may extend from the second surface 310 of the faceplate 300, and may extend partially through the faceplate 300 and fluidly couple with the bottom end of the first section 322. Second section 324 may be characterized by a substantially cylindrical profile as illustrated. A diameter of the second section 324 may be greater than a diameter of the first section 322. For example, the diameter of the second section 324 may be more than 1.5×, more than 1.75×, more than 2.0×, more than 2.25×, more than 2.5×, or greater than the diameter of the first section 322. In some embodiments, the second section 324 may extend at least about or greater than halfway, or at least about or greater than 75% of the way through a thickness of the faceplate between first surface 305 and second surface 310.

Aperture 320d is characterized by an aperture profile having a first section 326 that may extend from the first surface 305 of the faceplate 300, and may extend partially through the faceplate 300. In some embodiments, the first section 326 may extend at least about or greater than halfway, or at least about or greater than 75% of the way through a thickness of the faceplate between first surface 305 and second surface 310. First section 326 may be characterized by a substantially cylindrical profile as illustrated. A second section 328 may extend from the second surface 310 of the faceplate 300, and may extend partially through the faceplate 300 and fluidly couple with the bottom end of the first section 326. Second section 328 may be characterized by a substantially cylindrical profile as illustrated. A diameter of the first section 326 may be greater than a diameter of the first section 326. For example, the diameter of the first section 326 may be more than 1.5×, more than 1.75×, more than 2.0×, more than 2.25×, more than 2.5×, or greater than the diameter of the second section 328.

Aperture 320e may be characterized by an aperture profile including at least three sections. For example, a first section 330 may extend from the first surface 305 of the faceplate 300, and may extend partially through the faceplate 300. The first section 330 may be similar to the first section 326 of the aperture 320d. In some embodiments, the first section 330 may have a same or similar diameter as the first section 326 of the aperture 320. In some embodiments, the first section 330 may extend at least about or greater than halfway through a thickness of the faceplate 300 between first surface 305 and second surface 310. First section 330 may be characterized by a substantially cylindrical profile as illustrated.

The first section 330 may transition to an optional second section 332, which may operate as a choke in the faceplate 300, and may increase distribution or uniformity of flow. As illustrated, the second section 332 may include a taper from first section 330 to a narrower diameter. A diameter of the second section 332 may be less than a diameter of the first section 330. For example, the diameter of the first section 330 may be more than 1.5×, more than 1.75×, more than 2.0×, more than 2.25×, more than 2.5×, or greater than the diameter of the second section 328. In some embodiments, the diameter of the choke of the second section 332 may be the same or similar to the diameter of the second section 328 of the aperture 320d. However, a length of the second section 332 of each aperture 320e may be shorter than the second section 328 of each aperture 320d. For example, the second section 332 of each aperture 320e may be about or less than half as long as the second section 328 of each aperture 320d.

The second section 332 may then flare to a third section 334. Third section 334 may extend from a position partially through the faceplate to the second surface 310. Third section 334 may extend less than halfway through the thickness of the faceplate 300, for example, or may extend up to or about halfway through the faceplate 300. Third section 334 may be characterized by a tapered profile from the second surface 310 in some embodiments, and may extend to include a cylindrical portion intersecting a flare from second section 332, when included. Third section 334 may be characterized by a generally conical profile in some embodiments, or may be characterized by a countersunk profile, among other tapered profiles. A diameter of the third section 334 at the second surface 310 may be greater than a diameter of both the first section 330 and the second section 332. For example, the diameter of the third section 334 may be more than 1.5×, more than 1.75×, more than 2.0×, more than 2.25×, more than 2.5×, or greater than the diameter of the first section 330. The diameter of the third section 334 may be more than 3.5×, more than 4.0×, more than 4.5×, more than 5.0×, more than 5.25×, or greater than the diameter of the second section 332. The conical third section 334 of the aperture 320e may help increase the ion flux due to a pronounced hollow cathode effect in conical sections. This increased ion flux may translate directly into a localized deposition rate increase at regions of a substrate positioned beneath the aperture 320e.

Apertures 320f-320j are each characterized by aperture profiles having generally cylindrical first sections 336 that may extend from the first surface 305 of the faceplate 300. In some embodiments, the first section 336 may extend at least or about 5%, at least or about 10%, at least or about 20%, at least or about 30%, at least or about 40%, at least or about 50%, at least or about 60%, at least or about 70%, at least or about 80%, at least or about 90%, at least or about 95%, or more through a thickness of the faceplate between first surface 305 and second surface 310. A generally conical second section 338 may extend from an end of the first section 336 to the second surface 310 of the faceplate 300. A diameter of the second section 338 may be greater than a diameter of the first section 336. For example, the diameter of the second section 338 may be more than 1.5×, more than 1.75×, more than 2.0×, more than 2.25×, more than 2.5×, more than 2.75×, more than 3×, or greater than the diameter of the first section 336. The height of the second section 338 may be varied across the apertures 320f-320j while an angle of taper of each of the sidewalls of the second section 338 may be maintained at a constant angle as shown in apertures 320f-320h. The adjustment of the height of the conical sections may alter the hollow cathode effect at each aperture 320, with greater hollow cathode effects and ion flux being exhibited at apertures 320 having longer/taller conical sections, which may lead to increased localized deposition rates at regions of a substrate positioned beneath the respective aperture 320. Apertures 320 having shorter conical sections may exhibit lower hollow cathode effects and ion flux, which may lead to decreased localized deposition rates at regions of a substrate positioned beneath the respective aperture 320.

The angle of taper of each of the sidewalls of the second section 338 may be varied across the apertures 320f-320j while the height of the second section 338 may be constant angle as shown in apertures 320h and 320i. The adjustment of the angle or taper of the conical sections may alter the hollow cathode effect at each aperture 320, with greater hollow cathode effects and ion flux being exhibited at apertures 320 having flatter conical sections (e.g., lower angles relative to the second surface 310 of the faceplate 300), which may lead to increased localized deposition rates at regions of a substrate positioned beneath the respective aperture 320. Apertures 320 having steeper conical sections (e.g., higher angles relative to the second surface 310 of the faceplate 300) may exhibit lower hollow cathode effects and ion flux, which may lead to decreased localized deposition rates at regions of a substrate positioned beneath the respective aperture 320.

In some embodiments, the height and the angle of taper of each of the sidewalls of the second section 338 may be varied across the apertures 320f-320j as shown in apertures 320i and 320j. Depending on the combination of the height and angle of taper of each aperture 320, each aperture 320 may exhibit different hollow cathode effects and different ion flux, which may control the localized deposition rates at regions of a substrate positioned beneath the respective aperture 320.

Each conical section of apertures 320 may extend from between or about 5% and 100% of the thickness of the faceplate 300, between or about 5% and 90%, between or about 5% and 80%, between or about 5% and 70%, between or about 5% and 60%, between or about 5% and 50%, between or about 5% and 40%, between or about 5% and 30%, between or about 5% and 20%, between or about 5% and 10%. In a particular embodiment in which the conical section does not extend through a full thickness of the faceplate 300, the conical section may have a length of between or about 0.1 inches and 0.5 inches, between or about 0.2 inches and 0.4 inches, or about 0.3 inches. As noted above, taller conical sections may exhibit greater hollow cathode effects and ion flux, which may lead to increased localized deposition rates at regions of a substrate positioned beneath the respective aperture 320. An angle or taper of sidewalls of each of the conical sections of the aperture profiles may be greater than 0 degrees and less than 90 degrees relative to the second surface 310 of the faceplate 300. For example, the angle or taper of sidewalls of each of the conical sections may be between or about 5 degrees and 85 degrees, between or about 10 degrees and 80 degrees, between or about 15 degrees and 75 degrees, between or about 20 degrees and 70 degrees, between or about 25 degrees and 65 degrees, between or about 30 degrees and 60 degrees, between or about 35 degrees and 55 degrees, or between or about 40 degrees and 50 degrees. As noted above, flatter conical sections may exhibit greater hollow cathode effects and ion flux, which may lead to increased localized deposition rates at regions of a substrate positioned beneath the respective aperture 320.

As will be discussed in greater detail below, apertures having different aperture profiles may be positioned about an aperture region of a faceplate to improve film uniformity on a substrate. For example, for apertures positioned above and/or proximate areas of low deposition of a substrate, the aperture profiles may be selected to provide increased hollow cathode effects and ion flux to increase the deposition rate in such areas of the substrate. Similarly, apertures positioned above and/or proximate areas of high deposition may include aperture profiles that are selected to provide decreased hollow cathode effects and ion flux to reduce the deposition rate in such areas of the substrate. The design of the faceplate may be as simple or as complex as necessary to achieve a desired non-uniformity threshold for a given deposition operation.

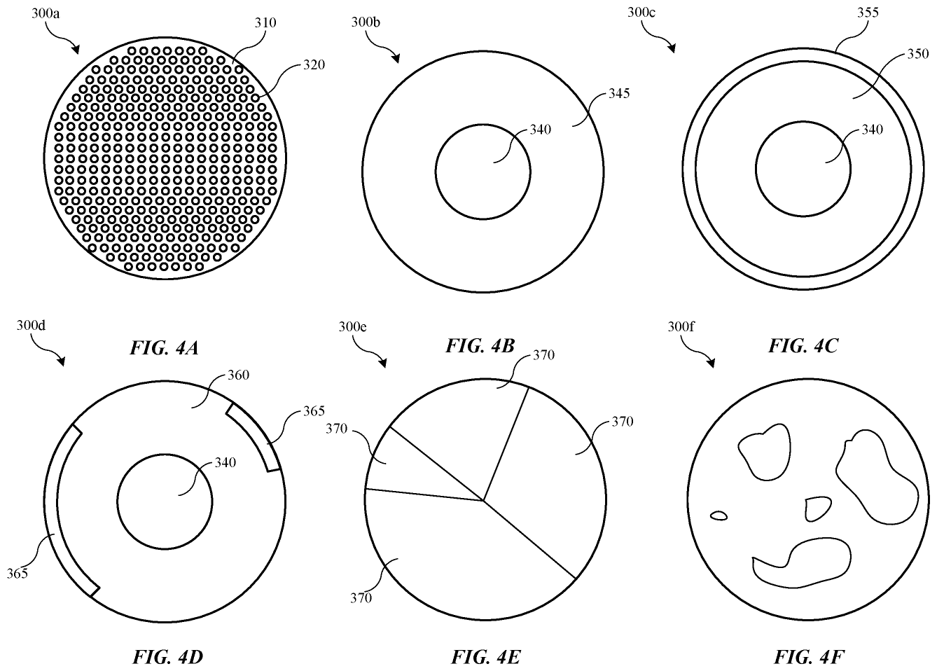

FIG. 4A shows a schematic bottom plan view of an aperture region of an exemplary faceplate 300a according to some embodiments of the present technology, and may illustrate a schematic view of faceplate 300a, for example, such as along second surface 310. As illustrated, faceplate 300a may include a plurality of apertures 320, which may be distributed in an array about the faceplate 300a. In some embodiments, the apertures 320 may be arranged as sets of rings extending radially outward along the faceplate 300. For example, from a central aperture 320, a first ring of apertures including a number of apertures, such as 8 apertures, extends about the central aperture. The next ring out, such as a second ring, may include 16 (or some other number) apertures extending about the first ring. This may follow the pattern as previously described for any number of rings as previously noted. The rings may be characterized by any number of shapes including circular or elliptical, as well as any other geometric pattern, such as rectangular, hexagonal, or any other geometric pattern that may include apertures distributed in a radially outward number of rings. It is to be understood that the figure is simply for illustrative purposes, and encompassed faceplates may be characterized by hundreds or thousands of apertures as noted previously, and which may be configured with any base number of apertures, for example. The apertures 320 may all illustrate a channel extending through the faceplate.

Each aperture 320 may have an aperture profile, such as the aperture profiles discussed in relation to apertures 320a-320j. Faceplate 300a may include apertures 320 having at least two different aperture profiles, with the different aperture profiles being distributed about the second surface 310 of the faceplate 300a in a manner to tune localized deposition rates to achieve a desired film profile and/or uniformity threshold. In some embodiments, each of the aperture profiles may include a conical section extending through the second surface 310 (such as shown in apertures 320a and 320e-320j). In some embodiments, the apertures 320 on faceplate 300a may include a combination of aperture profiles that include conical sections extending through the second surface 310 and aperture profiles that include cylindrical sections extending through the second surface 310 (such as shown in apertures 320b-320d).

FIG. 4B shows a schematic bottom plan view of an exemplary faceplate according to some embodiments of the present technology, and may illustrate a schematic view of a faceplate 300b, for example. Faceplate 300b may be understood to include any of the features or aspects described in relation to any of the other faceplates described herein in some embodiments. As illustrated, faceplate 300b may be divided into a number of zones, with each zone defining a number of apertures. For example, as illustrated faceplate 300b is divided into two zones. A first zone 340 may be generally circular in shape and is centered on the faceplate 300b. A number of apertures having a first aperture profile (such as one of the aperture profiles of apertures 320a-320j), may be arranged within the first zone 340. For example, the apertures within the first zone 340 may be arranged in a number of concentric rings from a center of the faceplate 300b towards an outer periphery of the first zone 340, although other patterns or arrangements of apertures within the first zone 340 are possible. A second zone 345 may be generally annular in shape. The second zone 345 may extend about and be concentric with the first zone 340. For example, the second zone 345 may extend from the outer periphery of the first zone 340 to the outer periphery of the faceplate 300b. A number of apertures having a second aperture profile (such as one of the aperture profiles of apertures 320a-320j) different than the first aperture profile may be arranged within the second zone 345. For example, the apertures within the second zone 345 may be arranged in a number of concentric rings from an inner edge of the second zone 345 towards an outer periphery of the second zone 345, although other patterns or arrangements of apertures within the second zone 345 are possible. Second zone 345 may be located at any radial outward dimension, or may begin at any percentage of the faceplate radius. For example, substrates may be characterized by any dimensions, such as rectangular or elliptical. For a circular substrate characterized by a 300 mm diameter, the radius of the substrate may be 150 mm. On the faceplate 300b, the second zone 345 may include apertures beyond 25 mm, 50 mm, 75 mm, 100 mm, 125 mm, etc. from the central axis. It is to be understood that similar modifications may be made for substrates of any other dimensions, such as 150 mm, 200 mm, 450 mm, 600 mm, or other dimensions of substrates as well. The second zone 345 may be located at a radial position beyond 10% of the substrate radius, beyond 25% of the substrate radius, beyond 50% of the substrate radius, beyond 60% of the substrate radius, beyond 70% of the substrate radius, beyond 80% of the substrate radius, beyond 90% of the substrate radius, beyond 95% of the substrate radius, or further, depending on the sought deposition characteristics at outer regions of the substrate.

The aperture profiles of the apertures within the first zone 340 may be selected to provide greater or lower localized deposition rates than the second zone 345 to address residual non-uniformity of film deposited on the substrate. While shown with two zones, it will be appreciated that faceplate 300b may be provided with any number zones to increase the granularity of the residual non-uniformity corrections. For example a circular (or polygonal) inner zone may be surrounded by at least or about two outer and/or intermediate zones, at least or about three outer and/or intermediate zones, at least or about four outer and/or intermediate zones, at least or about five outer and/or intermediate zones or more. Some or all of the zones may extend along a same radial interval (e.g., 10% or other portion of the radius), or may have different radial intervals.

FIG. 4C shows a schematic bottom plan view of an exemplary faceplate according to some embodiments of the present technology, and may illustrate a schematic view of a faceplate 300c, for example. Faceplate 300c may be understood to include any of the features or aspects described in relation to any of the other faceplates described herein in some embodiments. As illustrated, faceplate 300c may be divided into a number of zones, with each zone defining a number of apertures. For example, as illustrated faceplate 300c is divided into three zones. A first zone 340 may be generally circular in shape and is centered on the faceplate 300c. A number of apertures having a first aperture profile (such as one of the aperture profiles of apertures 320a-320j), may be arranged within the first zone 340. For example, the apertures within the first zone 340 may be arranged in a number of concentric rings from a center of the faceplate 300c towards an outer periphery of the first zone 340, although other patterns or arrangements of apertures within the first zone 340 are possible. A second zone 350 may be generally annular in shape. The second zone 350 may extend about and be concentric with the first zone 340. For example, the second zone 350 may extend from the outer periphery of the first zone 340 to an intermediate radius of the faceplate 300c. A number of apertures having a second aperture profile (such as one of the aperture profiles of apertures 320a-320j) different than the first aperture profile may be arranged within the second zone 350. For example, the apertures within the second zone 350 may be arranged in a number of concentric rings from an inner edge of the second zone 350 towards an outer periphery of the second zone 350, although other patterns or arrangements of apertures within the second zone 355 are possible. Second zone 350 may be located at any radial outward dimension, or may begin at any percentage of the faceplate radius. A third zone 355 may be generally annular in shape. The third zone 355 may extend about and be concentric with the second zone 350. For example, the third zone 355 may extend from the outer periphery of the second zone 350 to an outer periphery of the faceplate 300c. A number of apertures having the first aperture profile and/or third aperture profile different than the first aperture profile and the second aperture profile may be arranged within the third zone 355. For example, the apertures within the third zone 355 may be arranged in a number of concentric rings from an inner edge of the third zone 355 towards an outer periphery of the third zone 355, although other patterns or arrangements of apertures within the third zone 355 are possible. Third zone 355 may be located at any radial outward dimension, or may begin at any percentage of the faceplate radius.

The aperture profiles of the apertures within the first zone 340, second zone 350, and the third zone 355 may be selected to address residual non-uniformity of film deposited on the substrate. While shown with three zones, it will be appreciated that faceplate 300c may be provided with any number zones to increase the granularity of the residual non-uniformity corrections. For example a circular (or polygonal) inner zone may be surrounded by at least or about two outer and/or intermediate zones, at least or about three outer and/or intermediate zones, at least or about four outer and/or intermediate zones, at least or about five outer and/or intermediate zones or more. Some or all of the zones may extend along a same radial interval (e.g., 10% or other portion of the radius), or may have different radial intervals.

FIG. 4D shows a schematic bottom plan view of an exemplary faceplate according to some embodiments of the present technology, and may illustrate a schematic view of a faceplate 300d, for example. Faceplate 300d may be understood to include any of the features or aspects described in relation to any of the other faceplates described herein in some embodiments. As illustrated, faceplate 300d may be divided into a number of zones, with each zone defining a number of apertures. For example, as illustrated faceplate 300d is divided into four zones. A first zone 340 may be generally circular in shape and is centered on the faceplate 300d. A number of apertures having a first aperture profile (such as one of the aperture profiles of apertures 320a-320j), may be arranged within the first zone 340. For example, the apertures within the first zone 340 may be arranged in a number of concentric rings from a center of the faceplate 300d towards an outer periphery of the first zone 340, although other patterns or arrangements of apertures within the first zone 340 are possible. A second zone 360 may be generally annular in shape. The second zone 360 may extend about and be concentric with the first zone 340. For example, the second zone 360 may extend from the outer periphery of the first zone 340 to an intermediate radius and/or outer periphery of the faceplate 300d. As illustrated, a portion of the second zone 360 extends to the peripheral edge of the aperture region of the faceplate 300d, while a portion of the second zone 360 terminates at an intermediate radius of the faceplate 300d. A number of apertures having a second aperture profile (such as one of the aperture profiles of apertures 320a-320j) different than the first aperture profile may be arranged within the second zone 360. Second zone 350 may be located at any radial outward dimension, or may begin at any percentage of the faceplate radius. A number of arcuate zones 365 may be provided about the faceplate 300d. As shown, each arcuate zone 365 is positioned about the outer periphery of the faceplate 300d, however arcuate zones 365 may be positioned inward of the peripheral edge of the aperture region of faceplate 300d in some embodiments. Each arcuate zone 365 may be positioned at regular and/or irregular intervals. Some or all of the arcuate zones 365 may have a same or different thickness and/or length. As illustrated, a long arcuate zone 365 is positioned on one side of the faceplate 300d while a shorter arcuate zone 365 is positioned on a different side of the faceplate 300d. Each arcuate zone 365 may include number of apertures having the aperture profiles that are different than the second aperture profile. For example, the apertures within each arcuate zone 365 may be the same as within first zone 340. In other embodiments, one or all of the arcuate zones 365 may have apertures with different aperture profiles than the first zone 340. Some or all of the arcuate zones 365 may have apertures with the same or different aperture profiles.

The aperture profiles of the apertures within the first zone 340, second zone 360, and the arcuate zones 365 may be selected to address residual non-uniformity of film deposited on the substrate. While shown with four zones, it will be appreciated that faceplate 300d may be provided with any number zones to increase the granularity of the residual non-uniformity corrections.

FIG. 4E shows a schematic bottom plan view of an exemplary faceplate according to some embodiments of the present technology, and may illustrate a schematic view of a faceplate 300e, for example. Faceplate 300e may be understood to include any of the features or aspects described in relation to any of the other faceplates described herein in some embodiments. As illustrated, faceplate 300e may be divided into a number of zones, with each zone defining a number of apertures. For example, as illustrated faceplate 300e is divided into four zones. As illustrated, each zone is a radial zone 370, such as a wedge and/or other radial strip. Some or all of the radial zones 370 may each have the same size or different size in various embodiments. Adjacent radial zones 370 may include apertures having different aperture profiles. In some embodiments, each radial zone 370 may have apertures with unique aperture profiles, while in other embodiments some non-adjacent radial zones 370 may have apertures with the same aperture profiles. The aperture profiles of the apertures within the various radial zones 370 may be selected to address radial non-uniformity issues of film deposited on the substrate. While shown with four zones, it will be appreciated that faceplate 300e may be provided with greater numbers of radial zones to increase the granularity of the radial non-uniformity corrections.

FIG. 4F shows a schematic bottom plan view of an exemplary faceplate according to some embodiments of the present technology, and may illustrate a schematic view of a faceplate 300f, for example. Faceplate 300f may be understood to include any of the features or aspects described in relation to any of the other faceplates described herein in some embodiments. As illustrated, faceplate 300f may be divided into a number of zones or clusters, with each zone defining one or more apertures. For example, as illustrated faceplate 300f is divided into six zones. The zones may be distributed irregularly about the faceplate 300f in some embodiments. For example, each zone may have a specific size and shape to correct known film non-uniformity patterns on a wafer. For example, one or more test deposition operations may be performed to generate a film thickness profile. Based on the film thickness profile, faceplate 300f may be created with a customized layout of zones to improve the film non-uniformity. Adjacent zones may include apertures having different aperture profiles. In some embodiments, each zone may have apertures with unique aperture profiles, while in other embodiments some non-adjacent zones may have apertures with the same aperture profiles. The aperture profiles of the apertures within the various zones may be selected to address planar non-uniformity issues of film deposited on the substrate. While shown with six zones, it will be appreciated that faceplate 300f may be provided with greater numbers of radial zones to increase the granularity of the radial non-uniformity corrections.

As noted above, the faceplates 300 described herein are merely provided as examples. It will be appreciated that a faceplate may include any combination of radial, residual, planar, and/or other zones of apertures to improve film uniformity for a given film thickness profile. Additionally, granularity (e.g., a number of zones) of a faceplate may be increased to improve the film thickness uniformity to meet a particular threshold, with more precise thresholds including larger numbers of zones. For example, a faceplate may include at least or about two zones, at least or about three zones, at least or about four zones, at least or about five zones, at least or about 10 zones, at least or about 25 zones, at least or about 50 zones, at least or about 100 zones, at least or about 250 zones, at least or about 500 zones, at least or about 1000 zones, or more to provide more precise film uniformity tuning. In some embodiments, at least or about 50%, at least or about 60%, at least or about 70%, at least or about 80%, at least or about 90%, at least or about 95%, at least or about 97%, at least or about 99%, or all of the aperture profiles may be customized to achieve a substantially planar film thickness. In some embodiments, a single type of the generally conical aperture profiles may be present in no more than 50% of the plurality of apertures of the faceplate. For example, no single aperture profile may be used in more than half of the apertures.

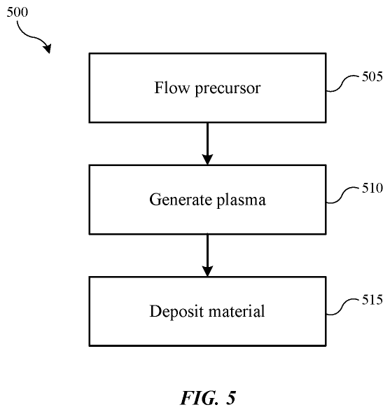

FIG. 5 shows operations of an exemplary method 500 of semiconductor processing according to some embodiments of the present technology. The method may be performed in a variety of processing chambers, including processing system 200 described above, which may include faceplates according to embodiments of the present technology, such as faceplate 300. Method 500 may include a number of optional operations, which may or may not be specifically associated with some embodiments of methods according to the present technology.

Method 500 may include a processing method that may include operations for forming a hardmask film or other deposition operations. The method may include optional operations prior to initiation of method 500, or the method may include additional operations. For example, method 500 may include operations performed in different orders than illustrated. In some embodiments, method 500 may include flowing one or more precursors into a processing chamber at operation 505. For example, the precursor may be flowed into a chamber, such as included in system 200, and may flow the precursor through one or more of a gasbox, a blocker plate, or a faceplate, prior to delivering the precursor into a processing region of the chamber.

In some embodiments, the faceplate may have two or more zones, with each zone defining a number of apertures. The apertures, similar to inner apertures 320, within adjacent zones may have different aperture profiles in order to tune local deposition rates and subsequently the film thickness non-uniformity by altering the hollow cathode effect at each aperture. Any of the other characteristics of faceplates described previously may also be included, including any aspect of faceplate 300, such as that at least some of the apertures may be characterized by a conical or countersunk profile. At operation 510, a plasma may be generated of the precursors within the processing region, such as by providing RF power to the faceplate to generate a plasma. Material formed in the plasma may be deposited on the substrate at operation 515. In some embodiments, depending on the thickness of the material deposited, the deposited material may be characterized by a thickness at the edge of the substrate that is approximately the same as a thickness within a central region of the substrate.

In some embodiments, method 500 may include producing and/or selecting a faceplate for use in the deposition operation. The faceplate may have a given pattern of zones with different aperture profiles as described above. For example, a film thickness profile may be provided and analyzed to identify thick and thin regions of the film. For example, sizes, shapes, locations, densities, and/or other characteristics of the thick and thin regions of the film may be identified. Based on the thick and thin regions of the film, a faceplate design may be generated. For example, based on the sizes, shapes, locations, densities, and/or other characteristics of the thick and thin regions of the film, a number of zones with different aperture profiles may be modeled about a surface of the faceplate. Based on experimental data associated with the effects of different aperture profiles (e.g., shape, size, height, degree of taper, etc.), additional computer modeling may be used to size, shape, and position a number of zones of different apertures for the faceplate design to alter deposition rates to even out the predicted film thickness across the substrate. Once designed, the faceplate may be fabricated. For example, the faceplate may be machined and/or otherwise manufactured. In some embodiments, the modeling may have sufficient data to generate an effective faceplate design in a single design operation. In other embodiments, the fabricated faceplate may be used in a number of test deposition operations to determine how effective the faceplate design is at improving the co-planarity across a substrate. number of iterative steps involving designing, fabricating, testing, and refining the faceplate may be performed to design the final faceplate used in deposition operations.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the protrusion” includes reference to one or more protrusions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor processing chamber, comprising:
a gas delivery assembly;
a substrate support; and
a faceplate positioned between the gas delivery assembly and the substrate support, wherein:
the faceplate is characterized by a first surface facing the gas delivery assembly and a second surface opposite the first surface;
the second surface of the faceplate and the substrate support at least partially define a processing region within the semiconductor processing chamber;
the faceplate defines a first plurality of apertures and a second plurality of apertures through the faceplate;
each of the first plurality of apertures comprises a first generally conical aperture profile that extends through the second surface of the faceplate that extends through the second surface of the faceplate;
each of the second plurality of apertures comprises a second generally conical aperture profile that extends through the second surface of the faceplate; and
the second generally conical aperture profile is different than the first generally conical aperture profile.

2. The semiconductor processing chamber of claim 1, wherein:
the second generally conical aperture profile and the first generally conical aperture profile comprise a different height, a different angle, or both a different height and a different angle.

3. The semiconductor processing chamber of claim 1, wherein:
the first generally conical aperture profile extends though the first surface of the faceplate.

4. The semiconductor processing chamber of claim 1, wherein:
each of the first plurality of apertures further comprises an upper aperture profile that extends through the first surface of the faceplate; and
the upper aperture profile is characterized by a substantially cylindrical profile.

5. The semiconductor processing chamber of claim 1, wherein:
each of the first plurality of apertures are disposed within one of a plurality of clusters of one or more apertures; and
the plurality of clusters are distributed irregularly about the faceplate.

6. The semiconductor processing chamber of claim 1, wherein:
a portion of each of the first plurality of apertures and a portion of each of the second plurality of apertures are characterized by a same diameter.

7. The semiconductor processing chamber of claim 6, wherein:
the first plurality of apertures are arranged about the faceplate in one or more zones; and
each of the one or more zones comprises multiple apertures of the first plurality of apertures.

8. The semiconductor processing chamber of claim 1, wherein:
each of the one or more zones is arranged about the second surface in a shape selected from the group consisting of a radial shape, an annular shape, an arcuate shape, a circle, and a polygon.

9. A semiconductor processing chamber faceplate, comprising:
a first surface and a second surface opposite the first surface, wherein:
the faceplate defines a first plurality of apertures and a second plurality of apertures through the faceplate;
each of the first plurality of apertures comprises a first generally conical aperture profile that extends through the second surface of the faceplate that extends through the second surface of the faceplate;
each of the second plurality of apertures comprises a second generally conical aperture profile that extends through the second surface of the faceplate; and
the second generally conical aperture profile is different than the first generally conical aperture profile.

10. The semiconductor processing chamber faceplate of claim 9, wherein:
an angle of each first generally conical aperture profile and each second generally conical aperture profile is between about 5 degrees and 85 degrees relative to the second surface of the faceplate.

11. The semiconductor processing chamber faceplate of claim 9, wherein:
a length of each first generally conical aperture profile and each second generally conical aperture profile is between about 0.1 inches and 0.5 inches.

12. The semiconductor processing chamber faceplate of claim 9, wherein:
the faceplate defines a third plurality of apertures through the faceplate;
each of the third plurality of apertures comprises a third generally conical aperture profile that extends through the second surface of the faceplate; and
the third generally conical aperture profile is different than the first generally conical aperture profile and the second generally conical aperture profile.

13. The semiconductor processing chamber faceplate of claim 9, wherein:
the faceplate defines a third plurality of apertures through the faceplate; and
each of the third plurality of apertures comprises a generally cylindrical aperture profile that extends through the second surface of the faceplate.

14. The semiconductor processing chamber faceplate of claim 9, wherein:
the first plurality of apertures are disposed within a central region of the faceplate; and
the second plurality of apertures are disposed within an outer region that is radially outward of the central region.

15. The semiconductor processing chamber faceplate of claim 14, wherein:
the central region is generally circular or polygonal in shape; and
the outer region is generally annular in shape.

16. The semiconductor processing chamber faceplate of claim 9, wherein:
a length of each first generally conical aperture profile and each second generally conical aperture profile extends through between about 5% and 50% of a thickness of the faceplate.

17. The semiconductor processing chamber faceplate of claim 9, wherein:
the faceplate comprises a central region, an outer region, and an intermediate region disposed between the central region and the outer region;
at least some of the first plurality of apertures are disposed within the central region of the faceplate;
at least some of the first plurality of apertures are disposed within the outer region of the faceplate; and
at least some of the second plurality of apertures are disposed within the intermediate region.

18. A semiconductor processing chamber faceplate, comprising:
a first surface and a second surface opposite the first surface, wherein:
the faceplate defines a plurality of apertures through the faceplate;
each of the plurality of apertures comprises a generally conical aperture profile; and
at least some of the generally conical aperture profiles have a different height, a different angle, or both a different height and a different angle.

19. The semiconductor processing chamber faceplate of claim 18, wherein:
the faceplate comprises apertures having at least five different types of generally conical aperture profiles.

20. The semiconductor processing chamber faceplate of claim 18, wherein:
a single type of the generally conical aperture profiles is present in no more than 50% of the plurality of apertures of the faceplate.
